(19) United States
(12) Patent Application Publication
(10) Pub. No.: US 2010/0044804 A1
(43) Pub. Date: Feb. 25, 2010

(54) NOVEL HIGH-K METAL GATE STRUCTURE AND METHOD OF MAKING

(75) Inventors: Chien-Hao Chen, Chuangwei Township (TW); Yong-Tian Hou, Singapore (SG); Kang-Cheng Lin, Yonghe City (TW); Kuo-Tai Huang, Hsinchu (TW)

Correspondence Address: HAYNES AND BOONE, LLP;IP Section, 2323 Victory Avenue, Suite 700, Dallas, TX, 75219, US

(73) Assignee: TAIWAN SEMICONDUCTOR MANUFACTURING COMPANY, LTD., Hsin-Chu (TW)

(21) Appl. No.: 12/427,222

(22) Filed: Apr. 21, 2009

Related U.S. Application Data
(60) Provisional application No. 61/091,650, filed on Aug. 25, 2008.

(51) Int. Cl. H01L 29/78; H01L 21/28

(52) U.S. Cl. 257/410; 438/585; 257/E29.255; 257/E21.19

(57) ABSTRACT

The present disclosure provides a semiconductor device that includes a semiconductor substrate, a transistor formed in the substrate, the transistor including a high-k gate dielectric formed over the substrate, the high-k gate dielectric having a first length measured from one sidewall to the other sidewall of the high-k gate dielectric, and a metal gate formed over the high-k gate dielectric, the metal gate having a second length measured from one sidewall to the other sidewall of the metal gate, the second length being smaller than the first length.

### PRIORITY DATA

This application claims priority to Provisional Application Ser. No. 61/091,650, filed on Aug. 25, 2008, entitled “NOVEL HIGH-K METAL GATE STRUCTURE AND METHOD OF MAKING,” the entire disclosure of which is incorporated herein by reference.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices. CMOS devices have typically been formed with a gate oxide and polysilicon gate electrode. There has been a desire to replace the gate oxide and polysilicon gate electrode with a high-k gate dielectric and metal gate electrode to improve device performance as feature sizes continue to decrease. However, problems arise when integrating a high-k/metal gate feature in a CMOS process flow. For example, during gate patterning or gate etching, the edges of the high-k and metal layers may be damaged. Further, during subsequent thermal processing, the high-k and metal materials may be contaminated. Thus, performance characteristics such as carrier mobility, threshold voltage, and reliability may degrade.

### SUMMARY

One of the broader forms of an embodiment of the present invention involves a semiconductor device. The semiconductor device includes a semiconductor substrate and a transistor formed in the substrate. The transistor includes a high-k gate dielectric formed over the substrate, the high-k gate dielectric having a first length measured from one sidewall to the other sidewall of the high-k gate dielectric and a metal gate formed over the high-k gate dielectric, the metal gate having a second length measured from one sidewall to the other sidewall of the metal gate, the second length being smaller than the first length.

Another one of the broader forms of an embodiment of the present invention involves a method of fabricating a semiconductor device. The method includes providing a semiconductor substrate, forming a high-k dielectric layer over the semiconductor substrate, forming a metal gate layer over the high-k dielectric layer, removing a portion of the metal gate layer to form a first portion of a gate structure, the first portion having a first length that extends form one sidewall to the other sidewall of the partially removed metal gate layer, and removing a portion of the high-k dielectric layer to form a second portion of the gate structure, the second portion having a second length that extends from one sidewall to the other sidewall of the partially removed high-k dielectric layer, the second length being larger than the first length.

Yet another one of the broader forms of an embodiment of the present invention involves a integrated circuit comprising a semiconductor substrate and a device formed in the substrate. The device includes a high-k gate dielectric formed over the substrate, a metal gate formed over the high-k gate dielectric, the metal gate having a first sidewall and a second sidewall; and a sealing layer formed on the first and second sidewalls of the metal gate. The high-k dielectric includes a first portion that extends beyond the first sidewall of the metal gate by a first length and a second portion that extends beyond the second sidewall of the metal gate by a second length.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart illustrating a method for fabricating a semiconductor device having a non-planar vertical sidewalls for a gate structure according to various aspects of the present disclosure;

FIGS. 2A to 2F are cross-sectional views of a semiconductor device at various stages of fabrication according to the method of FIG. 1;

FIG. 3 is a cross-sectional view of a semiconductor device having an alternative sealing structure for the gate structure of FIG. 2; and

FIG. 4 is a cross-sectional view of a semiconductor device having a sloped profile for a high-k gate dielectric.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

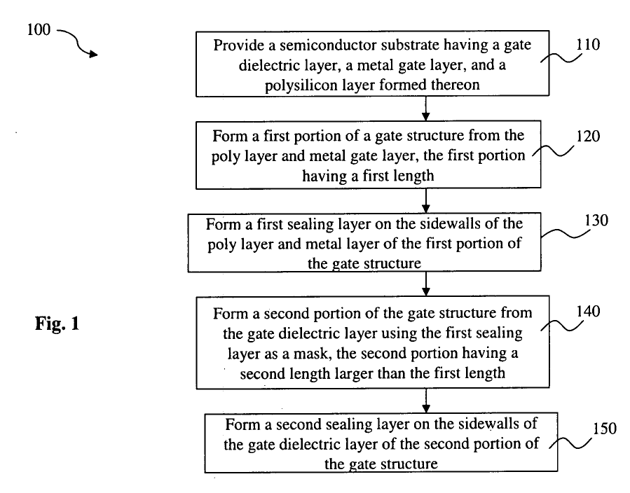

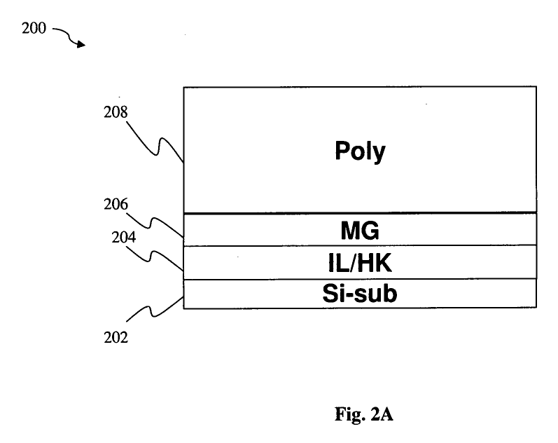

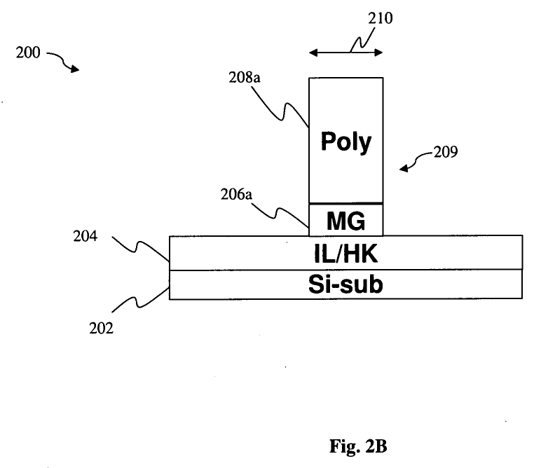

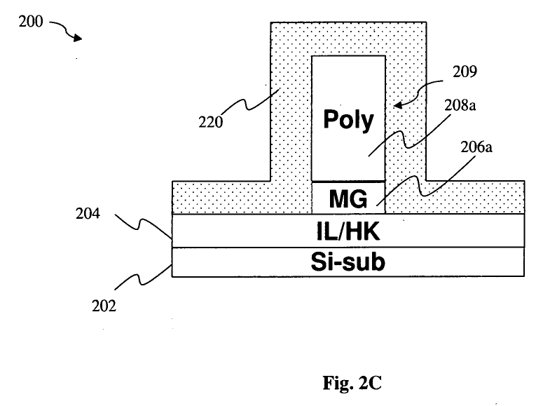

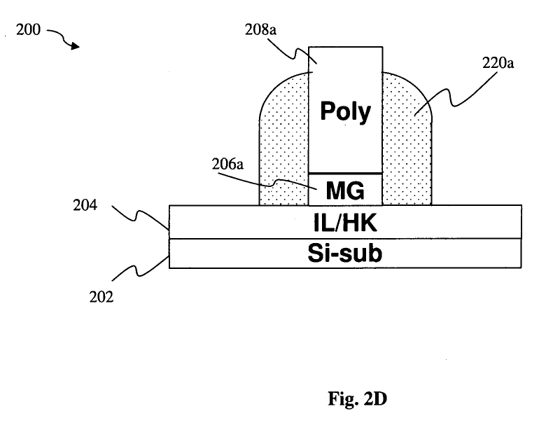

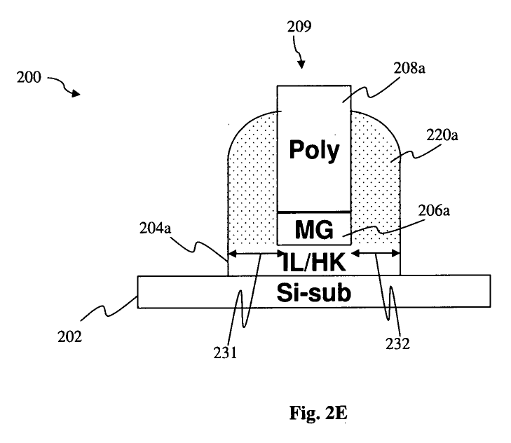

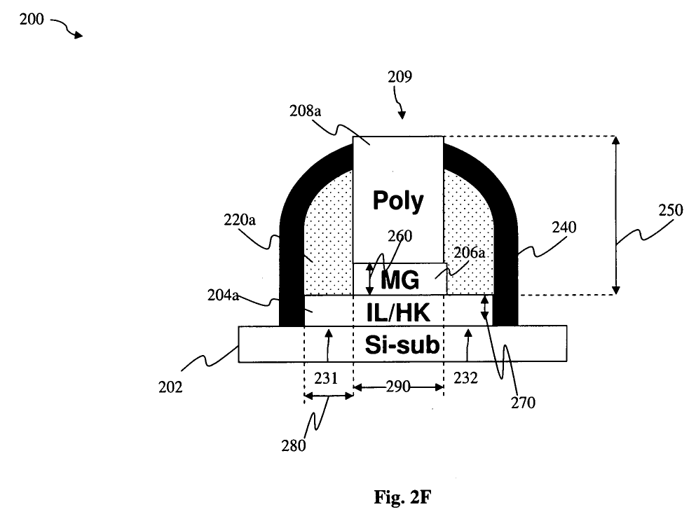

Referring to FIG. 1, illustrated is a flowchart of a method 100 for fabricating a semiconductor device having a non-planar vertical sidewalls for a gate structure according to various aspects of the present disclosure. Referring also to FIGS. 2A to 2F, illustrated are cross-sectional views of a semiconductor at various stages of fabrication according to the method 100 of FIG. 1. It is understood that part of the semiconductor device 200 may be fabricated with normal CMOS technology processes, and thus some processes are briefly described herein. Also, FIGS. 2A to 2F are simplified for a better understanding of the inventive concepts of the present disclosure. For example, although the figures illustrate a gate stack for a single device, it is understood the semiconductor device 200 may include a number of various devices including transistors, resistors, capacitors, fuses, etc. that form an integrated circuit (IC).

The method 100 begins with block 110 in which a semiconductor substrate may be provided, the substrate having a gate dielectric layer, metal layer, and poly layer formed thereon. In FIG. 2A, the semiconductor device 200 may include a semiconductor substrate 202 such as a silicon substrate. The substrate 202 may alternatively include silicon germanium, gallium arsenic, or other suitable semiconductor materials. The substrate 202 may further include other features such as various doped regions, a buried layer, and/or an epitaxy layer. Furthermore, the substrate 202 may be a semiconductor on insulator such as silicon on insulator (SOI). In other embodiments, the semiconductor substrate 202 may include a doped epi layer, a gradient semiconductor layer, and/or may further include a semiconductor layer overlying another semiconductor layer of a different type such as a silicon layer on a silicon germanium layer. In other examples, a compound semiconductor substrate may include a multilayer silicon structure or a silicon substrate may include a multilayer compound semiconductor structure.

The semiconductor device 200 may further include an isolation structure (not shown) such as a shallow trench isolation (STI) feature formed in the substrate 202 for isolating active region in the substrate as is known in the art. The isolation structure may be formed of silicon oxide, silicon nitride, silicon oxynitride, fluoride-doped silicate (FSG), and/or a low k dielectric material known in the art.

The semiconductor device 200 may further include a gate dielectric layer 204 including an interfacial layer/high-k dielectric layer formed over the substrate 202. The interfacial layer may include a silicon oxide layer having a thickness ranging from about 5 to about 10 angstrom (A). The interfacial layer may be formed on the substrate 202. The high-k dielectric layer may be formed on the interfacial layer by atomic layer deposition (ALD), chemical vapor deposition (CVD), or other suitable technique. The high-k dielectric layer may include a thickness ranging from about 10 to about 40 angstrom (A). The high-k dielectric layer may include hafnium oxide (HfO₂). Alternatively, the high-k dielectric layer may optionally include other high-k dielectrics such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), and combinations thereof. The semiconductor device 200 may further include a capping layer for tuning a work function of the gate electrode for properly performing as an NMOS transistor device and a PMOS transistor device, respectively. For example, the capping layer may include lanthanum oxide, LaSiO, manganese oxide, aluminum oxide, or other suitable materials. The capping layer may be formed on the high-k dielectric layer or underneath the high-k dielectric layer.

The semiconductor device 200 may further include a metal gate layer 206 formed over the gate dielectric layer 204. The metal gate layer 206 may include a thickness ranging from about 10 to about 500 angstrom (A). The metal gate layer 206 may be formed by various deposition techniques such as CVD, physical vapor deposition (PVD or sputtering), plating, or other suitable technique. The metal gate layer 206 may include TiN, TaN, ZrSi₂, MoSi₂, TaSi₂, NiSi₂, WN, combinations thereof, or other suitable material. The semiconductor device 200 may further include a polysilicon or poly layer 208 formed on the metal gate layer 206 by deposition or other suitable process.

The method 100 continues with block 120 in which a first portion of a gate structure may be formed from the poly layer and the metal gate layer, the first portion of a gate structure having a first length. In FIG. 2B, the semiconductor device 200 may further include a hard mask (not shown) formed over the poly layer 208. The hard mask may be formed by a deposition process or other suitable process. The hard mask may include silicon nitride, silicon oxynitride, silicon carbide, or other suitable material. A patterned photoresist layer (not shown) may be formed by a photolithography process for gate patterning. The photolithography process may include spin coating, soft-baking, exposure, post-baking, developing, rinsing, drying, and other suitable process. Alternatively, the patterning may be performed by immersion lithography, electron beam lithography, or other suitable process. An etch process may be performed to pattern the hard mask, and the hard mask may be used to pattern the poly layer 208 and metal gate layer 206 to form part of a gate structure 209. The etch process may have a high selectivity such that the etch process may stop at the gate dielectric layer 204. The patterned photoresist layer and hard mask may be removed by stripping or other suitable process. Accordingly, the gate structure 209 may include a poly layer 208a and a metal gate layer 206a having a length 210 measured along a channel length. The length 210 may depend on the process technology (e.g., 90 nm, 65 nm, 45 nm, and below).

The method 100 continues with block 130 in which a first sealing layer may be formed on the sidewalls of the poly layer and the metal gate layer. In FIG. 2C, a sealing layer 220 may be formed over the gate structure 209 and the gate dielectric layer 204 by CVD or other suitable deposition process. The sealing layer 220 may include a dielectric material such as silicon nitride (SiNₓ), silicon oxide (SiOₓ), silicon oxynitride (SiON), silicon carbide (SiC), or other suitable material. In some embodiments, the sealing layer 220 may include silicon (Si) or silicon germanium (SiGe). Alternatively, the sealing layer 220 may optionally include an oxygen gettering material such as a dielectric containing Ti, Ta, Zr, Hf, W, Mo, and/or combinations thereof. The sealing layer 220 may include a single layer or multiple layer configuration. For example, the sealing layer 220 may include an oxygen gettering material layer and a layer including silicon-rich dielectric and/or nitrogen containing dielectric. In FIG. 2D, an etching process such as a dry etching technique (e.g., anisotropic etching) may be performed on the sealing layer 220 such that only a portion 220a of the sealing layer remains on the sidewalls of the metal gate layer 206a, and on some or all of the sidewalls of the poly layer 208a. The thickness of the sealing layer 220a may depend on the desired extension of the gate dielectric layer as discussed below. It should be noted that the sealing layer 220a may protect the metal gate layer 206a from damage or loss when etching the underlying high-k dielectric material, and may also prevent oxidation during subsequent processing.

The method 100 continues with block 140 in which a second portion of the gate structure may be formed by from the gate dielectric layer using the first sealing layer as a mask, the second portion of the gate stack having a second length greater than the first length. In FIG. 2E, an etch process such as a wet etch may be performed on the gate dielectric layer 204 using the sealing layer 220a as a protective mask. The wet etch process may have a high selectivity such that the etch process may stop at the semiconductor substrate 202. Alternatively, a dry etch process may optionally be performed to remove the unprotected gate dielectric layer 204. Following the etch process, the gate structure 209 may further include the gate dielectric layer 204a having a portion 231 that extends from one of the sidewalls of the metal gate layer 206a to an outer edge of the sealing layer 220a, and a portion 232 that extends from the other one of the sidewalls of the metal gate layer 206a to the other outer edge of the sealing layer 220a. The extended portions 231, 232 may be precisely controlled by optimizing the etch process that forms the sealing layer 220a.

The method 100 continues with block 150 in which a second sealing layer may be formed on the sidewalls of the gate dielectric layer of the second portion of the gate structure. In FIG. 2F, a sealing layer 240 may be formed on the sidewalls of the gate dielectric layer 204a, sealing layer 220a, and some of the poly layer 208a by a deposition and etching process similar to the formation of the sealing layer 220a. The sealing layer 240 may be formed by CVD or other suitable deposition process. An etch process such as a dry etch process (stops at the substrate 202) may be performed on the sealing layer such that only a portion of the sealing layer remains on the sidewalls of the gate dielectric layer 204a and on the sealing layer 220a. The sealing layer 240 may function to prevent exposure of the high-k get dielectric. The sealing layer 240 may include a dielectric material such as silicon nitride (SiNₓ), silicon oxide (SiOₓ), silicon oxynitride (SiON), silicon carbide (SiC), or other suitable material. In some embodiments, the sealing layer 140 may include silicon (Si) or silicon germanium (SiGe). In some other embodiments, the sealing layer 240 may be formed of the same material as the sealing layer 220a. In still some other embodiments, the sealing layer 240 may be formed of a different material than the sealing layer 220a. In other embodiments, the sealing layer 240 may include a low-k dielectric material. In yet other embodiments, the sealing layer layers 220a, 240 may include a single layer or multiple layer configuration.

The poly layer 208a and metal gate layer 206a of the first portion of the gate structure 209 may have a thickness 250 ranging from 50 to about 5000 angstrom, and preferably a thickness ranging from about 100 to about 1000 angstrom. The metal gate layer 206a of the first portion of the gate structure 209 may have a thickness 260 ranging from about 0 to about 500 angstrom, and preferably a thickness ranging from about 10 to about 100 angstrom. The gate dielectric layer 204a (including the interfacial layer/high-k dielectric layer) of the second portion of the gate structure 209 may include a thickness 270 ranging from about 10 to about 500 angstrom, and preferably a thickness ranging from about 10 to about 50 angstrom. The portions 231, 232 of the gate dielectric layer 204 may have an extension 280 ranging from 10 to about 500 angstrom, and preferably an extension ranging from about 20 to about 100 angstrom.

It should be noted that the during the etching of the gate dielectric layer 204 some portion of the high-k dielectric may be damaged due to the chemicals and strong reactions of the etching process. However, the portion that may be damaged is away from a channel region 290 of the transistor. In other words, the extended portions 231, 232 of the gate dielectric layer 204a may function as a buffer to prevent damage to the high-k dielectric 204a in the channel region 290. Thus, the high-k dielectric 204a in the channel region 290 may have a better quality (than extended portions 231, 232), and thus may provide better carrier mobility and reliability. Further, the extended portions 231, 232 may also function as a buffer to minimize oxygen contamination into the channel, and thus the threshold voltage of the transistor may be easier to control. In contrast, a vertical gate structure having a metal gate and high-k dielectric with substantially the same dimensions does not provide this buffer, That is, the edge of the high-k dielectric and metal gate may be damaged during etching and/or other processing. Also, the edge of high-k dielectric may be contaminate by oxygen penetrating the sealing layer. Accordingly, once the high-k dielectric is contaminated, the high-k quality, carrier mobility, threshold voltage control, and reliability may all seriously degrade.

Thereafter, it is understood that the semiconductor device 200 may undergo further CMOS process flow to form various features and structures such as lightly doped drain regions (LDD), sidewall spacers, source/drain regions, silicide regions, contact etch stop layer (CESL), inter-level dielectric (ILD), contacts/vias, metal layers, passivation layer, and so forth.

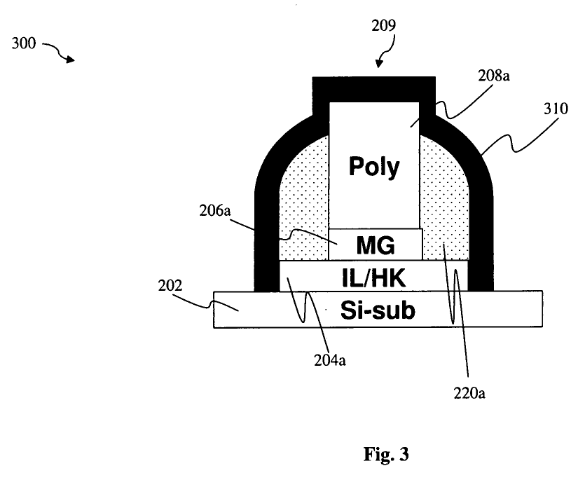

Referring to FIG. 3, illustrated is a cross-sectional view of a semiconductor device 300 having an alternative sealing configuration for the gate structure of FIG. 2. The semiconductor 300 may be similar to the semiconductor device 200 of FIG. 2 except for the sealing configuration. Similar features in FIGS. 2 and 3 are numbered the same for the sake of simplicity and clarity. It is understood that various sealing configurations may be implemented to protect the non-vertical gate structure 209. In the present example, the semiconductor device 300 may include a sealing layer 220a that covers the metal gate layer 206a and may be used to form the extended portions of the gate dielectric layer 204a. The semiconductor device 300 may further include a sealing layer 310 that substantially covers the entire gate structure 209 including sidewalls of the gate dielectric layer 204a, the sealing layer 220a, and the poly layer 208a. Thereafter, the semiconductor 300 may undergo further CMOS process flow as discussed above.

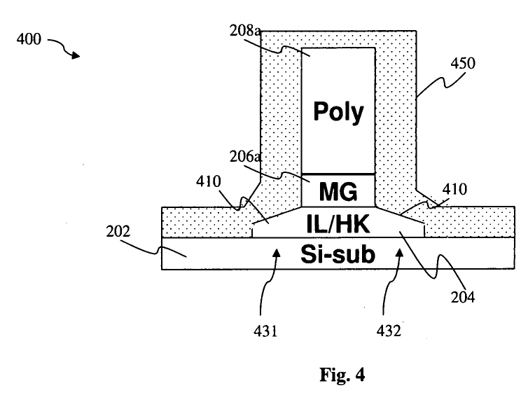

Referring to FIG. 4, illustrated is a cross-sectional view of a semiconductor device 400 having a sloped profile for a high-k gate dielectric. The semiconductor device 400 may be similar to the semiconductor device 200 of FIG. 2 except for the differences discussed below. Similar features in FIGS. 2 and 4 are numbered the same for the sake of simplicity and clarity. The semiconductor device 400 may include a semiconductor substrate 202, an interfacial layer/high-k dielectric (IL/HK) layer 204 formed on the substrate 202, a metal gate layer 206 formed on the IL/HK layer 204, and a poly layer 208 formed on the metal gate layer 206. A first etch process may be performed to form the poly layer 208a and metal gate layer 206a for a first portion of the gate structure, and the first etch may stop at the IL/HK layer 204. A sloped profile 410 may result on extended portions 431, 432 of the IL/HK layer 204 during a second etching process. However, the sloped extended portions 431, 432 may function as a buffer to prevent damage to the high-k dielectric within a channel region as was discussed in FIG. 2. A sealing layer 450 (similar to the sealing layer 220a of FIG. 2) may be deposited over the substrate 202 and gate structure, and may be etch to seal and cover the metal gate layer 206a and the IL/HK layer 204 to protect these layers during subsequent processing.

The present invention achieves different advantages in various embodiments disclosed herein. For example, the present disclosed method provides a simple and cost-effective non-vertical gate structure that improves device performance and reliability by reducing the risk of damage (e.g., loss or contamination) to the high-k dielectric and metal gate during semiconductor processing. The methods and devices disclosed herein may be easily integrated with current CMP process flow and thus are applicable in future and advanced technologies. In some embodiments, the high-k gate dielectric may have various shapes due to a different etch profile control. In other embodiments, the non-vertical gate structure may be sealed by various configurations to protect the high-k dielectric and metal gate during semiconductor processing. It is understood that different embodiments disclosed herein offer different advantages, and that no particular advantage is necessarily required for all embodiments.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, the methods and devices disclosed herein may be implemented in a gate first process, a gate last process, or hybrid process. In the gate first process, a true metal gate structure may be formed first and may be followed by normal process flow to fabricate the final device. In the gate last process, a dummy poly gate structure may be formed first and may continue with normal process flow until deposition of an interlayer dielectric (ILD), and thereafter the dummy poly gate structure may be removed and replaced with a true metal gate structure. In the hybrid gate process, the metal gate for one device (NMOS or PMOS device) may be formed first and the metal gate for another device (PMOS or NMOS) may be formed last. Further, although the methods and devices disclosed herein are implemented with a CMOS process flow, it is understood that other technologies may benefit from the disclosed embodiments as well.

What is claimed is:

1. A semiconductor device comprising:
a semiconductor substrate; and
a transistor formed in the substrate, the transistor including:
a high-k gate dielectric formed over the substrate, the high-k gate dielectric having a first length measured from one sidewall to the other sidewall of the high-k gate dielectric; and
a metal gate formed over the high-k gate dielectric, the metal gate having a second length measured from one sidewall to the other sidewall of the metal gate, the second length being smaller than the first length.

2. The semiconductor device of claim 1, wherein the transistor further includes an interfacial layer formed between the substrate and the high-k gate dielectric, the interfacial layer having the first length.

3. The semiconductor device of claim 1, wherein transistor further includes a first sealing layer for sealing each of the sidewalls of the metal gate and a second sealing layer for sealing each of the sidewalls of the high-k gate dielectric.

4. The semiconductor device of claim 3, wherein the first sealing layer is formed of a same material as the second sealing layer.

5. The semiconductor device of claim 3, wherein the first sealing layer includes an oxygen gettering material.

6. The semiconductor device of claim 3, wherein the first sealing layer and second sealing layer each includes one of silicon nitride, silicon oxide, silicon oxynitride, silicon carbide, silicon, and silicon germanium.

7. The semiconductor device of claim 1, wherein the transistor further includes a polysilicon layer formed on the metal gate layer, the polysilicon layer having the second length.

8. The semiconductor device of claim 1, wherein the high-k gate dielectric includes portions extending beyond each of the sidewalls of the metal gate, the portions having sloped profiles.

9. The semiconductor device of claim 9, wherein the portions each have an extension ranging from about 20 to about 100 angstrom (A).

10. A method of fabricating a semiconductor device comprising:
providing a semiconductor substrate;
forming a high-k dielectric layer over the semiconductor substrate;
forming a metal gate layer over the high-k dielectric layer;
removing a portion of the metal gate layer to form a first portion of a gate structure, the first portion having a first length that extends form one sidewall to the other sidewall of the partially removed metal gate layer; and
removing a portion of the high-k dielectric layer to form a second portion of the gate structure, the second portion having a second length that extends from one sidewall to the other sidewall of the partially removed high-k dielectric layer, the second length being larger than the first length.

11. The method of claim 10, further comprising, prior to removing the portion of the high-k dielectric layer, forming a first sealing layer on each of the sidewalls of the partially removed metal gate layer.

12. The method of claim 11, wherein the first sealing layer includes an oxygen gettering material.

13. The method of claim 11, wherein the removing the portion of the high-k dielectric layer includes etching a portion of the high-k dielectric layer that is not protected by the first sealing layer and the partially removed metal gate layer.

14. The method of claim 11, further comprising, after removing the portion of the high-k dielectric layer, forming a second sealing layer on each of the sidewalls of the partially removed high-k dielectric layer.

15. The method of claim 14, wherein the first sealing layer and second sealing layer each includes one of silicon nitride, silicon oxide, silicon oxynitride, silicon carbide, silicon, and silicon germanium.

16. The method of claim 10, further comprising:
forming a polysilicon layer on the metal gate layer; and
removing a portion of the polysilicon layer to form the first portion of the gate structure, the partially removed polysilicon layer having the first length.

17. An integrated circuit comprising a semiconductor substrate and a device formed in the substrate, the device including:
a high-k gate dielectric formed over the substrate;
a metal gate formed over the high-k gate dielectric, the metal gate having a first sidewall and a second sidewall; and
a sealing layer formed on the first and second sidewalls of the metal gate;
wherein the high-k gate dielectric includes a first portion that extends beyond the first sidewall of the metal gate by a first length and a second portion that extends beyond the second sidewall of the metal gate by a second length.

18. The integrated circuit of claim 17, wherein the sealing layer covers the first and second portions of the high-k gate dielectric.

19. The integrated circuit of claim 17, wherein the device further includes:
another sealing layer formed on the sealing layer and on each of the sidewalls of the high-k gate dielectric; and
spacers formed on the another sealing layer.

20. The integrated circuit of claim 17, wherein the first and second portions each includes a length ranging from about 20 to about 100 angstrom.
